(19) United States
(12) Patent Application Publication
(10) Pub. No.: US 2026/0106078 A1
(43) Pub. Date: Apr. 16, 2026

(54) ACOUSTIC WAVE DEVICE WITH NEGATIVE TEMPERATURE COEFFICIENT OF PERMITTIVITY CAPACITOR

(71) Applicant: Skyworks Solutions, Inc., Irvine, CA (US)

(72) Inventors: Rei Goto, Osaka-Shi (JP); Michael David Hill, Emmitsburg, MD (US); Joshua James Caron, Summerfield, NC (US)

(21) Appl. No.: 19/355,854

(22) Filed: Oct. 10, 2025

Related U.S. Application Data
(60) Provisional application No. 63/706,503, filed on Oct. 11, 2024.
(60) Provisional application No. 63/706,525, filed on Oct. 11, 2024.

(51) Int. Cl. H01G 4/12; H03H 9/145

(52) U.S. Cl. CPC H01G 4/1254; H03H 9/145

(57) ABSTRACT

An acoustic wave device comprising a resonator and a capacitor electrically coupled to the resonator, the capacitor including a first conductive layer, a second conductive layer, and a dielectric material between the first conductive layer and the second conductive layer. The dielectric material has a negative temperature coefficient of permittivity.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to interdigital transducer (IDT) capacitors and surface acoustic wave (SAW) devices including a resonator and a capacitor.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A SAW resonator can include an interdigital transductor electrode on a piezoelectric substrate. The SAW resonator can generate a surface acoustic wave on a surface of the piezoelectric layer on which the interdigital transductor electrode is disposed.

There are technical challenges related to meeting certain filter specifications with acoustic wave filters. For example, filters with steep skirts and relatively low insertion loss near band edges are typically desirable. Meeting certain filter specifications related to skirt steepness and/or low insertion loss while also meeting other filter specifications can be challenging.

### SUMMARY

In some aspects, the techniques described herein relate to an acoustic wave device including: a resonator; and a capacitor electrically coupled to the resonator, the capacitor including a first conductive layer, a second conductive layer, and a dielectric material between the first conductive layer and the second conductive layer, the dielectric material having a negative temperature coefficient of permittivity.

In some aspects, the techniques described herein relate to an acoustic wave device wherein the resonator is electrically coupled in series with the capacitor.

In some aspects, the techniques described herein relate to an acoustic wave device wherein the resonator is electrically coupled in parallel with the capacitor.

In some aspects, the techniques described herein relate to an acoustic wave device further includes a second capacitor electrically coupled in series with the resonator.

In some aspects, the techniques described herein relate to an acoustic wave device wherein the dielectric material has a temperature coefficient of permittivity in a range between negative 500 ppm/K and negative 10,000 ppm/K.

In some aspects, the techniques described herein relate to an acoustic wave device wherein the dielectric material has a temperature coefficient of permittivity in a range between negative 800 ppm/K and negative 5,000 ppm/K.

In some aspects, the techniques described herein relate to an acoustic wave device wherein the dielectric material includes titanium oxide, barium titanate, lead zirconate titanate, strontium titanate, tantalum oxide, magnesium oxide, or barium strontium titanate.

In some aspects, the techniques described herein relate to an acoustic wave device wherein the dielectric material includes titanium dioxide.

In some aspects, the techniques described herein relate to an acoustic wave device wherein the resonator is a surface acoustic wave resonator.

In some aspects, the techniques described herein relate to an acoustic wave device wherein the resonator is a multilayer piezoelectric substrate surface acoustic wave resonator.

In some aspects, the techniques described herein relate to an acoustic wave device wherein the resonator is a bulk acoustic wave resonator.

In some aspects, the techniques described herein relate to an acoustic wave device wherein the capacitor is formed on a multilayer piezoelectric substrate.

In some aspects, the techniques described herein relate to an acoustic wave device wherein the multilayer piezoelectric substrate includes a support substrate, a piezoelectric layer, and an intermediate layer between the support substrate and the piezoelectric layer.

In some aspects, the techniques described herein relate to an acoustic wave device wherein the first conductive layer of the capacitor and an interdigital transducer electrode of the resonator includes the same material.

In some aspects, the techniques described herein relate to a capacitor configured to couple to an acoustic wave resonator, the capacitor including: a first conductive layer; a second conductive layer; and an insulator between the first conductive layer and the second conductive layer, the insulator including a dielectric material having a negative temperature coefficient of permittivity.

In some aspects, the techniques described herein relate to a capacitor wherein the dielectric material has a temperature coefficient of permittivity in a range between negative 500 ppm/K and negative 10,000 ppm/K.

In some aspects, the techniques described herein relate to a method of forming an acoustic wave device, the method including: providing a resonator; and electrically coupling a capacitor to the resonator, the capacitor including a first conductive layer, a second conductive layer, and a dielectric material between the first conductive layer and the second conductive layer, the dielectric material having a negative temperature coefficient of permittivity.

In some aspects, the techniques described herein relate to a method wherein electrically coupling the capacitor to the resonator includes connecting the capacitor in series with the resonator.

In some aspects, the techniques described herein relate to a method wherein electrically coupling the capacitor to the resonator includes connecting the capacitor in parallel with the resonator.

In some aspects, the techniques described herein relate to a method wherein the dielectric material includes titanium oxide, barium titanate, lead zirconate titanate, strontium titanate, tantalum oxide, magnesium oxide, or barium strontium titanate.

In some aspects, the techniques described herein relate to an acoustic wave device including: a resonator; and an interdigital transducer capacitor electrically coupled to the resonator, the interdigital transducer capacitor including an interdigital transducer structure and a dielectric material in thermal communication with the interdigital transducer structure, the dielectric material having a negative temperature coefficient of permittivity.

In some aspects, the techniques described herein relate to an acoustic wave device wherein the resonator is electrically coupled in series with the interdigital transducer capacitor.

In some aspects, the techniques described herein relate to an acoustic wave device wherein the resonator is electrically coupled in parallel with the interdigital transducer capacitor.

In some aspects, the techniques described herein relate to an acoustic wave device further includes a second capacitor electrically coupled in series with the resonator.

In some aspects, the techniques described herein relate to an acoustic wave device wherein the dielectric material has a temperature coefficient of permittivity in a range between negative 500 ppm/K and negative 10,000 ppm/K.

In some aspects, the techniques described herein relate to an acoustic wave device wherein the dielectric material has a temperature coefficient of permittivity in a range between negative 800 ppm/K and negative 5,000 ppm/K.

In some aspects, the techniques described herein relate to an acoustic wave device wherein the dielectric material includes titanium oxide, barium titanate, lead zirconate titanate, strontium titanate, tantalum oxide, magnesium oxide, or barium strontium titanate.

In some aspects, the techniques described herein relate to an acoustic wave device wherein the dielectric material includes titanium dioxide.

In some aspects, the techniques described herein relate to an acoustic wave device wherein the resonator is a surface acoustic wave resonator.

In some aspects, the techniques described herein relate to an acoustic wave device wherein the resonator is a bulk acoustic wave resonator.

In some aspects, the techniques described herein relate to an acoustic wave device wherein the interdigital transducer structure is formed on a multilayer piezoelectric substrate.

In some aspects, the techniques described herein relate to an acoustic wave device wherein the multilayer piezoelectric substrate includes a support substrate, a piezoelectric layer, and an intermediate layer between the support substrate and the piezoelectric layer.

In some aspects, the techniques described herein relate to an acoustic wave device wherein the dielectric material is positioned over the interdigital transducer structure.

In some aspects, the techniques described herein relate to an acoustic wave device wherein the dielectric material is positioned between the interdigital transducer structure and the piezoelectric layer.

In some aspects, the techniques described herein relate to a capacitor configured to couple to an acoustic wave resonator, the capacitor including: an interdigital transducer structure; and a dielectric material in thermal communication with the interdigital transducer structure, the dielectric material having a negative temperature coefficient of permittivity.

In some aspects, the techniques described herein relate to a capacitor wherein the dielectric material has a temperature coefficient of permittivity in a range between negative 500 ppm/K and negative 10,000 ppm/K.

In some aspects, the techniques described herein relate to a method of forming an acoustic wave device, the method including: providing a resonator; and electrically coupling an interdigital transducer capacitor to the resonator, the interdigital transducer capacitor including an interdigital transducer structure and a dielectric material in thermal communication with the interdigital transducer structure, the dielectric material having a negative temperature coefficient of permittivity.

In some aspects, the techniques described herein relate to a method wherein electrically coupling the interdigital transducer capacitor to the resonator includes connecting the interdigital transducer capacitor in series with the resonator.

In some aspects, the techniques described herein relate to a method wherein electrically coupling the interdigital transducer capacitor to the resonator includes connecting the interdigital transducer capacitor in parallel with the resonator.

In some aspects, the techniques described herein relate to a method wherein the dielectric material includes titanium oxide, barium titanate, lead zirconate titanate, strontium titanate, tantalum oxide, magnesium oxide, or barium strontium titanate.

### BRIEF DESCRIPTION OF THE DRAWINGS

Embodiments of this disclosure will now be described, by way of non-limiting example, with reference to the accompanying drawings.

FIG. 1A is a schematic top plan view of an acoustic wave device according to an embodiment.

FIG. 1B is a schematic cross-sectional side view of the acoustic wave device of FIG. 1A.

FIG. 2 is a graph showing simulated TCFs at the resonant frequency and the anti-resonant frequency of the acoustic wave device as a function of a capacitor area.

FIG. 3 is a graph showing simulated ΔTCFs of the acoustic wave device and a SAW device that includes an IDT capacitor as a function of coupling coefficient K2.

FIG. 4A is a schematic top plan view of an acoustic wave device according to an embodiment.

FIG. 4B is a schematic cross-sectional side view of the acoustic wave device of FIG. 4A.

FIG. 5A is a schematic top plan view of an acoustic wave device according to an embodiment.

FIG. 5B is a schematic cross-sectional side view of the acoustic wave device of FIG. 5A.

FIG. 6A is a schematic circuit diagram of an acoustic device according to an embodiment.

FIG. 6B is a schematic circuit diagram of an acoustic device according to an embodiment.

FIG. 7A is a schematic diagram of an example filter that includes surface acoustic wave devices according to an embodiment.

FIG. 7B is a schematic diagram of another filter that includes surface acoustic wave devices according to an embodiment.

FIG. 8 is a schematic diagram of a radio frequency module that includes a surface acoustic wave resonator according to an embodiment.

FIG. 9 is a schematic diagram of a radio frequency module that includes filters with surface acoustic wave resonators according to an embodiment.

FIG. 10 is a schematic block diagram of a module that includes an antenna switch and duplexers that include a surface acoustic wave resonator according to an embodiment.

FIG. 11A is a schematic block diagram of a module that includes a power amplifier, a radio frequency switch, and duplexers that include a surface acoustic wave resonator according to an embodiment.

FIG. 11B is a schematic block diagram of a module that includes filters, a radio frequency switch, and a low noise amplifier according to an embodiment.

FIG. 12A is a schematic block diagram of a wireless communication device that includes a filter with a surface acoustic wave resonator in accordance with one or more embodiments.

FIG. 12B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate (MPS) SAW device. A bandwidth of a filter is defined as the range of frequencies over which the device can effectively filter signals. A larger effective electromechanical coupling coefficient or coupling factor (kt²) can contribute to providing a wider bandwidth for a SAW device. However, when a relatively large kt² SAW resonator is used in a filter, the skirt performance and the insertion loss of the filter can be degraded.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate surface acoustic wave (MPS-SAW) device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, a larger static capacitance can enable size reduction of a SAW device. In some SAW devices, performance can be degraded when a magnitude of a temperature coefficient of frequency (TCF) is large. Therefore, a temperature compensation layer can be provided to bring the TCF of the SAW device closer to zero. A thickness of the temperature compensation layer can affect the TCF, the coupling coefficient K², and spurious of the resonator under which the temperature compensation layer is disposed.

A temperature compensation layer can be provided over an interdigital transducer (IDT) electrode in a SAW device to form a temperature compensated (TC) SAW device. In the TC-SAW device, the IDT electrode is positioned between the piezoelectric layer and the temperature compensation layer. Another structure that can be beneficial for compensating the temperature increase in the SAW device is a multi-layer piezoelectric substrate (MPS) structure. An MPS-SAW device can include a support substrate, a piezoelectric layer over the support substrate, and the IDT electrode over the piezoelectric layer. There may be one or more functional layers provided between the support substrate and the piezoelectric layer. Silicon dioxide (SiO₂) is known to have a positive TCF which can bring the TCF of the SAW device closer to zero and a deposited SiO₂ layer can be an example of the functional layer. MPS-SAW devices can thermally insulate an interdigital transducer electrode and a piezoelectric layer. By reducing dissipative thermal impedance of the SAW device, the ruggedness and power handling can be improved.

However, the MPS-SAW can have a relatively larger temperature coefficient of frequency (TCF) difference (ΔTCF) between a TCF of the resonant frequency and a TCF of the anti-resonant frequency as compared to other types of SAW devices such as the TC-SAW devices. The ΔTCF can be significant for maintaining a stable voltage standing wave ratio (VSWR) and preserving a passband width over temperature. When the ΔTCF is significantly large, the frequency gap between the resonant and anti-resonant points will change with temperature, which may lead to impedance mismatches. This variation can cause the VSWR to fluctuate, potentially increasing signal reflection and degrading performance. A relatively small ΔTCF can help ensure stable impedance matching, reducing changes in the VSWR across varying temperatures.

A capacitor coupled in parallel with a resonator can shift the CTF of the anti-resonant frequency and a capacitor coupled in series with the resonator can shift the CTF of the resonant frequency. When the capacitance is increased, the coupling coefficient K² can be smaller. There can be a tradeoff between the ΔTCF and the coupling coefficient K², and it can be challenging to provide both a relatively small ΔTCF and a relatively large coupling coefficient K².

In various embodiments disclosed herein, a capacitor having a negative temperature coefficient of capacitance or permittivity (TCεr) can be coupled with the resonator. The negative TCεr capacitor can, when coupled in parallel with the resonator, shift the CTF of the anti-resonant frequency down more than it does at higher temperatures. This is the opposite of the natural behavior that the resonator. The negative TCεr capacitors disclosed herein can reduce the ΔTCF while maintaining a relatively large coupling coefficient K².

A negative TCεr capacitor disclosed herein can be coupled in parallel with a resonator, in some embodiments, to shift the CTF of the anti-resonant frequency. In some other embodiments, the negative TCεr capacitor disclosed herein can be coupled in series with the resonator to shift the CTF of the resonant frequency. The negative TCεr capacitor can have any suitable capacitor structures. For example, the negative TCεr capacitor can be a conductor-insulator-conductor capacitor (e.g., a metal-insulator-metal (MIM) capacitor) or an interdigital transducer (IDT) capacitor.

The conductor-insulator-conductor capacitor can include a first conductive layer, a second conductive layer, and an insulator (e.g., a dielectric material) between the first conductive layer and the second conductive layer. The IDT capacitor can include an interdigital transducer structure and a dielectric material in thermal communication with the IDT structure. The dielectric material in the conductor-insulator-conductor capacitor and the dielectric material of the IDT capacitor can include a negative temperature coefficient of permittivity. In some embodiments, the dielectric material can have a temperature coefficient of permittivity in a range between negative 500 ppm/K and negative 10,000 ppm/K.

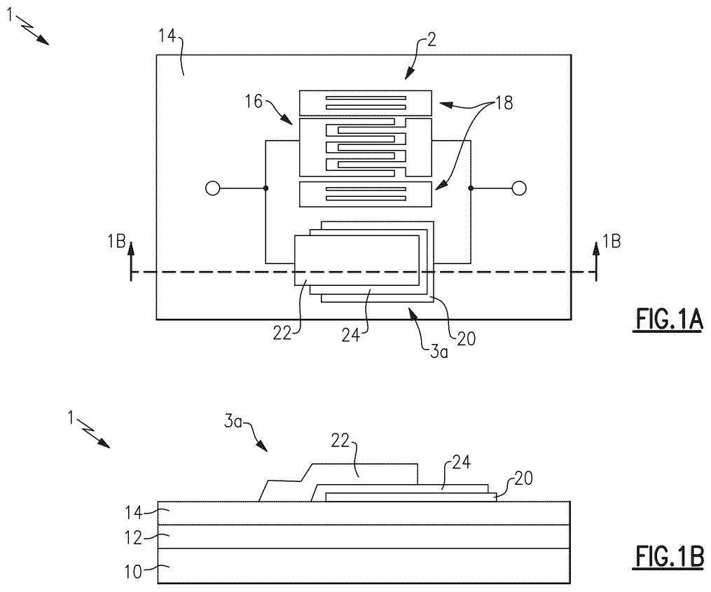

FIG. 1A is a schematic top plan view of an acoustic wave device 1 according to an embodiment. FIG. 1B is a schematic cross-sectional side view of the acoustic wave device 1 of FIG. 1A. The acoustic wave device 1 can include a resonator 2 and a capacitor 3a. The illustrated resonator 2 is an example of a surface acoustic wave (SAW) device. Any suitable principles and advantages of capacitors disclosed herein can be used with any other types of SAW devices, such as bulk acoustic wave devices. The capacitor 3a is an example of a conductor-insulator-conductor capacitor (e.g., metal-insulator-metal (MIM) capacitor).

The acoustic wave device 1 can include a multilayer piezoelectric substrate (MPS) that includes a support substrate 10, an intermediate layer 12, and a piezoelectric layer 14. The resonator 2 can include an interdigital transducer (IDT) electrode 16 and a pair of reflectors 18. The capacitor 3a can include a first conductive layer 20, a second conductive layer 22, and an insulator 24 between the first conductive layer 20 and the second conductive layer 22.

The capacitor 3a can be a negative TCεr capacitor that includes a negative TCεr material as the insulator 24. The insulator 24 can have a dielectric material. In some embodiments, the insulator 24 can have a temperature coefficient of permittivity in a range between negative 500 ppm/K and negative 10,000 ppm/K, negative 500 ppm/K and negative 5,000 ppm/K, negative 800 ppm/K and negative 5,000 ppm/K, or negative 1000 ppm/K and negative 2,500 ppm/K. For example, the insulator 24 can be titanium oxide (e.g., titanium dioxide (TiO₂)), barium titanate (BaTiO₃), lead zirconate titanate (PZT), strontium titanate (SrTiO₃), tantalum oxide (Ta₂O₅), magnesium oxide (MgO), or barium strontium titanate (BST). When the insulator 24 includes a material that has a larger dielectric constant, the size of the capacitor 3a may be reduced.

The first conductive layer 20 and the second conductive layer 22 can include any conductive material. For example, the first conductive layer 20 and the second conductive layer 22 can be metal layers. In some embodiments, the first conductive layer 20 and the second conductive layer 22 can include the same material. However, in some other embodiments, the first conductive layer 20 and the second conductive layer 22 can include different materials. For example, materials of the first conductive layer 20 and the second conductive layer 22 can be selected from tungsten (W) aluminum (Al), copper (Cu), Magnesium (Mg), titanium (Ti), molybdenum (Mo), etc., or alloys, such as AlMgCu, AlCu, etc.

The IDT electrode 16 of the resonator 2 can have a single layer structure or a multi-layer structure that includes two or more conductive layers. The IDT electrode 16 can include any suitable IDT electrode material. For example, the IDT electrode can include molybdenum (Mo), aluminum (Al), copper (Cu), Magnesium (Mg), titanium (Ti), tungsten (W), the like, or any suitable combination thereof. The IDT electrode 16 may include alloys, such as AlMgCu, AlCu, etc. The IDT electrode 16 is in electrical communication with the piezoelectric layer 14. In some embodiments, the IDT electrode 16 can be at least partially positioned in the piezoelectric layer 14. The IDT electrode 16 can be positioned between the pair of reflectors 18.

The support substrate 10 can be any suitable substrate layer, such as a silicon layer. The support substrate 10 can have a relatively high acoustic impedance. An acoustic impedance of the support substrate 10 can be higher than an acoustic impedance of the piezoelectric layer 14. For instance, the support substrate 10 can have a higher acoustic impedance than an acoustic impedance of lithium niobate and a higher acoustic impedance than lithium tantalate. The acoustic impedance of the support substrate 10 can be higher than an acoustic impedance of silicon dioxide (SiO₂). The resonator 2 including the piezoelectric layer 14 on a support substrate 10 with relatively high thermal conductivity, such as silicon substrate, can achieve better thermal dissipation compared to a similar resonator without the high impedance support substrate 10.

The piezoelectric layer 14 can include any suitable piezoelectric layer, such as a lithium based piezoelectric layer. In some embodiments, the piezoelectric layer 14 can be a lithium tantalate (LT) layer. For example, the piezoelectric layer 14 can be an LT layer having a cut angle of 20° (20° Y-cut X-propagation LT) or a cut angle of 60° (60° Y-cut X-propagation LT). For example, the piezoelectric layer 14 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118° Y-cut X-propagation LN) or more or a cut angle of about 132° (132 Y-cut X-propagation LN) or less. For example, the piezoelectric layer 14 can be 125±20° Y-cut LN, 125±15° Y-cut LN, 125±10° Y-cut LN, or 125±5° Y-cut LN. A thickness of the piezoelectric layer 14 can be selected based on a wavelength λ or L of a surface acoustic wave generated by the resonator 2 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5, 0.1 L to 0.3 L, or 0.1 L to 0.2 L. Selecting the thickness of the piezoelectric layer 14 from these ranges can be critical in avoiding significant frequency variation and providing sufficient temperature coefficient of frequency for the resonator 2. In some embodiments, the piezoelectric layer 14 can include lithium tantalate (LT) and lithium niobate (LN).

The intermediate layer 12 can be referred to as a functional layer in some applications. The intermediate layer 12 can be, for example, a single crystal layer. In some embodiments, the intermediate layer 12 can be a silicon oxide layer (e.g., a silicon dioxide (SiO₂) layer. In some embodiments, the intermediate layer 12 can function as an adhesion layer. In some embodiments, a thickness of the intermediate layer 12 can be the same as, generally similar to, or thinner than the thickness of the piezoelectric layer 14.

As illustrated in FIG. 1A, the capacitor 3a can be electrically coupled in parallel with the resonator 2. However, the capacitor 3a can be coupled in series with the resonator 2 in some other embodiments. When the capacitor 3a is coupled in parallel with the resonator 2, the TCF of the anti-resonant frequency can be shifted.

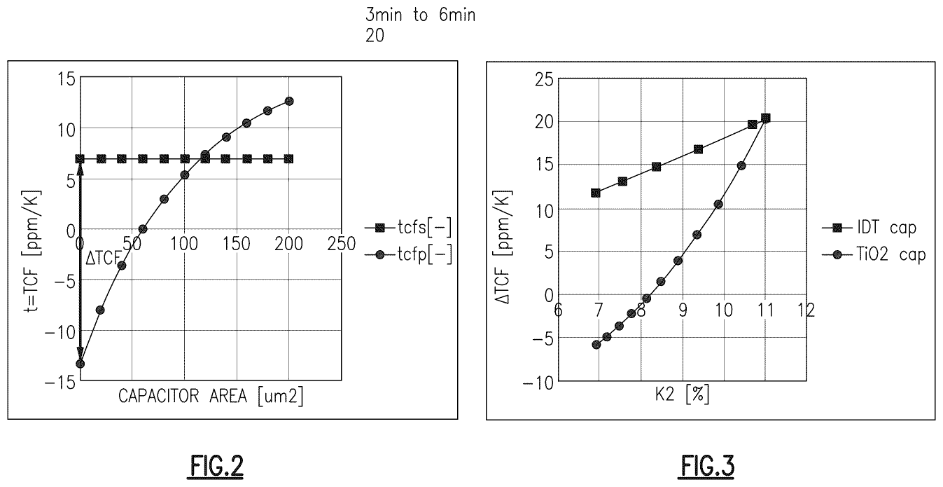

FIG. 2 is a graph showing simulated TCFs at the resonant frequency and the anti-resonant frequency of the acoustic wave device 1 as a function of a capacitor area. In the simulation, a 100 nm thick TiO₂ layer is used as the insulator 24. The graph of FIG. 2 indicates that as the capacitor area increases the TCF at the anti-resonant frequency increases. Therefore, the capacitor area of the capacitor 3a can be selected to have a desired TCF at the anti-resonant frequency. The TCF at the resonant frequency is generally maintained. The capacitor area of the capacitor 3a can be selected to provide a desired ΔTCF.

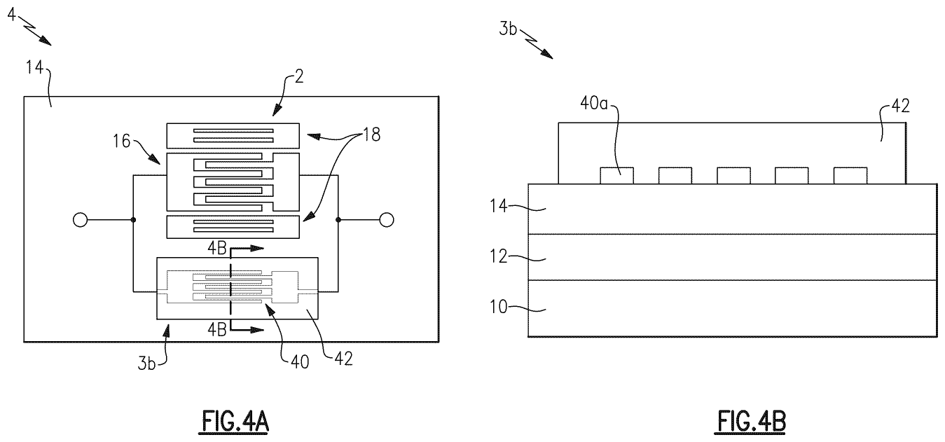

FIG. 3 is a graph showing simulated ΔTCFs of the acoustic wave device 1 and a SAW device that includes an IDT capacitor as a function of coupling coefficient K². With the IDT capacitor, the ΔTCF can be improved but the coupling coefficient K² is degraded significantly. The acoustic wave device 1 that includes the capacitor 3a can improve the ΔTCF significantly more with less degradation in the coupling coefficient K². Therefore, the acoustic wave device 1 that includes the capacitor 3a can provide a better trade-off between the ΔTCF and coupling coefficient K² than the IDT capacitor. For example, when the ΔTCF is about 15 ppm/K, the coupling coefficient K² is about 8.2% for the IDT capacitor, while coupling coefficient K² is about 15% for the capacitor 3a. Also, when the coupling coefficient K² is about 9%, the ΔTCF is about 16 ppm/K for the IDT capacitor, while the ΔTCF is about 5 ppm/K for the capacitor 3a. The capacitor 3a can contribute to reducing the overall size of the acoustic wave device 1. For example, to obtain the coupling coefficient K² of about 9%, a lateral size of the IDT capacitor can be about 3600 μm², while a lateral size of the capacitor 3a can be about 80 μm².

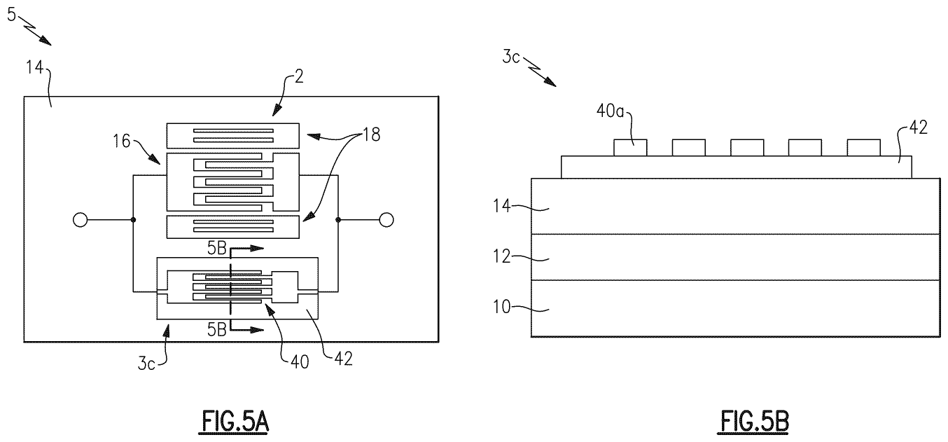

The negative TCεr capacitor according to various embodiments disclosed herein can provide a significant ΔTCF improvement with a relatively low impact on the coupling coefficient K². Any suitable principles and advantages disclosed herein regarding a negative TCεr material can be implemented in any suitable capacitor structures. For example, the negative TCεr material can be implemented in an IDT capacitor as shown in FIGS. 4A-5B.

FIG. 4A is a schematic top plan view of an acoustic wave device 4 according to an embodiment. FIG. 4B is a schematic cross-sectional side view of the acoustic wave device 4 of FIG. 4A. Unless otherwise noted, the components of the acoustic wave device 4 shown in FIGS. 4A and 4B may be structurally and/or functionally the same as or generally similar to like components disclosed herein.

The acoustic wave device 4 can include a resonator 2 and a capacitor 3b. The capacitor 3b is an example of an IDT capacitor. The capacitor 3b can be a negative TCεr capacitor that includes a negative TCεr material.

The acoustic wave device 4 can include a multilayer piezoelectric substrate (MPS) that includes a support substrate 10, an intermediate layer 12, and a piezoelectric layer 14. The resonator 2 can include an interdigital transducer (IDT) electrode 16 and a pair of reflectors 18. The capacitor 3b can include an IDT structure 40 and a negative TCεr material layer 42. The IDT structure 40 of the capacitor 3b can include a plurality of capacitor fingers 40a.

As with the capacitor 3a disclosed herein, the capacitor 3b shown in FIGS. 4A and 4B that includes the negative TCεr material layer 42 can be a negative TCεr capacitor. Therefore, when the capacitor 3b is electrically coupled in parallel with the resonator 2, the ΔTCF can be significantly improved while maintaining a relatively high coupling coefficient K².

The location of the negative TCεr material layer 42 may not be limited to that shown in FIGS. 4A and 4B. For example, the negative TCεr material layer 42 can be positioned between the piezoelectric layer 14 and the IDT structure 40 as shown in FIGS. 5A and 5B.

FIG. 5A is a schematic top plan view of an acoustic wave device 5 according to an embodiment. FIG. 5B is a schematic cross-sectional side view of the acoustic wave device 5 of FIG. 5A. Unless otherwise noted, the components of the acoustic wave device 5 shown in FIGS. 5A and 5B may be structurally and/or functionally the same as or generally similar to like components disclosed herein.

The acoustic wave device 5 can include a resonator 2 and a capacitor 3c. The capacitor 3c is an example of an IDT capacitor. The capacitor 3c can be a negative TCεr capacitor that includes a negative TCεr material.

The acoustic wave device 5 can include a multilayer piezoelectric substrate (MPS) that includes a support substrate 10, an intermediate layer 12, and a piezoelectric layer 14. The resonator 2 can include an interdigital transducer (IDT) electrode 16 and a pair of reflectors 18. The capacitor 3c can include an IDT structure 40 and a negative TCεr material layer 42. The IDT structure 40 of the capacitor 3c can include a plurality of capacitor fingers 40a.

As with the capacitors 3a, 3b disclosed herein, the capacitor 3c shown in FIGS. 5A and 5B that includes the negative TCεr material layer 42 can be a negative TCεr capacitor. Therefore, when the capacitor 3c is electrically coupled in parallel with the resonator 2, the ΔTCF can be significantly improved while maintaining a relatively high coupling coefficient K².

When the negative TCεr material layer 42 is positioned over the IDT structure 40 as shown in FIGS. 4A and 4B, it can be manufactured relatively easily and it can provide a good capacitor tunability. When the negative TCεr material layer 42 is positioned between the piezoelectric layer 14 and the IDT structure 40 as shown in FIGS. 5A and 5B, there can be more electric flux in the negative TCεr material layer 42 than when the negative TCεr material layer 42 is provided in other locations such that it can more effectively suppress an unwanted acoustic response.

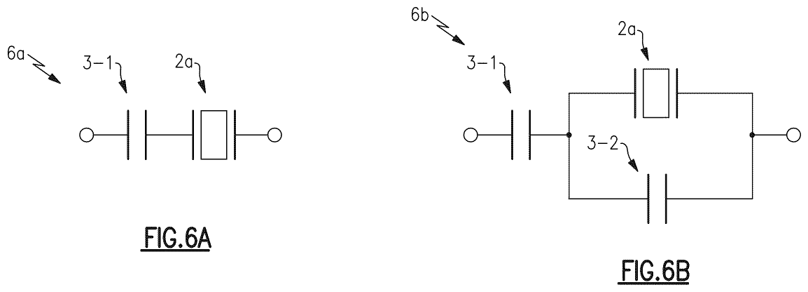

The capacitors (e.g., the capacitors 3a, 3b, 3c) disclosed herein can be electrically coupled in parallel with a resonator (see FIGS. 1A, 1B, and 4A-5B) to shift the CTF of the anti-resonant frequency, or in series with the resonator (see FIG. 6A) to shift the CTF of the resonant frequency. In some embodiments, an acoustic wave device can include a capacitor that is electrically coupled in parallel with a resonator and another capacitor that is electrically coupled in parallel with the resonator (see FIG. 6B).

FIG. 6A is a schematic circuit diagram of an acoustic device 6a according to an embodiment. The acoustic wave device 6a includes a resonator 2a and a capacitor 3-1. The resonator 2a can be any suitable resonator. For example, the resonator 2a can be a SAW resonator or a BAW resonator. The capacitor 3-1 can be a negative TCεr capacitor in accordance with any suitable principles and advantages disclosed herein.

FIG. 6B is a schematic circuit diagram of an acoustic device 6b according to an embodiment. The acoustic wave device 6b includes a resonator 2a and capacitors 3-1, 3-2. The resonator 2a can be any suitable resonator. For example, the resonator 2a can be a SAW resonator or a BAW resonator. The capacitor 3-1 can be a negative TCεr capacitor in accordance with any suitable principles and advantages disclosed herein, and the capacitor 3-2 can be a negative TCεr capacitor in accordance with any suitable principles and advantages disclosed herein. The capacitor 3-1 is electrically coupled in series with the resonator 2a and the capacitor 3-2 is electrically coupled in parallel with the resonator 2a. The capacitor 3-1 can contribute to shifting the CTF of the resonant frequency and the capacitor 3-2 can contribute to shifting the CTF of the anti-resonant frequency.

An acoustic wave device including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more packaged MPS-SAW devices disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

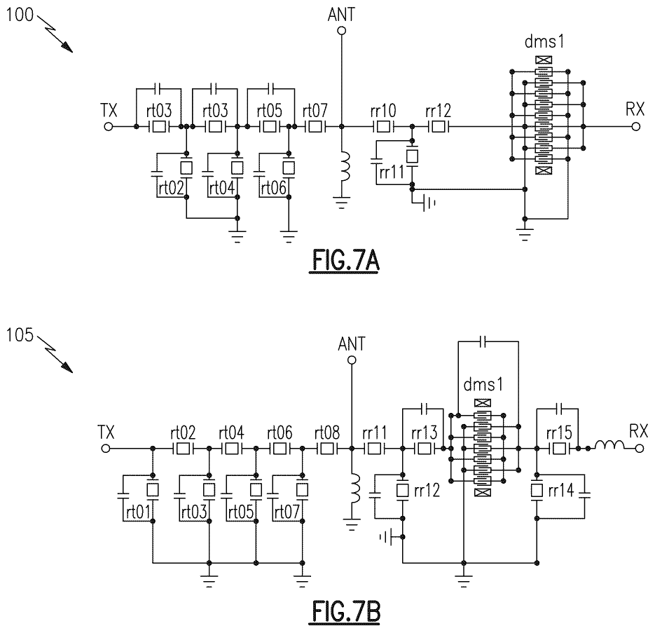

FIG. 7A is a schematic diagram of an example multiplexer 100 that includes surface acoustic wave devices according to an embodiment. The multiplexer 100 can be a duplexer. The multiplexer 100 includes a transmit filter and a receive filter. For example, the transmit filter can be a band pass filter. The illustrated transmit filter in the multiplexer 100 is arranged to filter a radio frequency signal received at a transmit port TX and provide a filtered output signal to an antenna port ANT. The illustrated receive filter in the multiplexer 100 is arranged to filter a radio frequency signal received at the antenna port ANT and provide a filtered output to a receive port RX. The transmit filter includes resonators rt01 to rt07. The resonators rt01, rt03, rt05 are series resonators and rt02, rt04, tr06 are shunt resonators. The receive filter includes resonators rr10, rr11, rr12, and a multi-mode SAW filter (e.g., a double mode SAW filter dms1). The resonators rr10, rr12 are series resonators and the resonator rr1 is a shunt resonator.

The multiplexer 100 also includes capacitors coupled in parallel with the resonators rt01, rt02, rt03, rt04, rt05, rt06, rr11. The capacitors can include one or more capacitors in accordance with any suitable principles and advantages disclosed herein. The transmit filter and the receive filter of the multiplexer 100 can have a relatively small gap between passbands.

FIG. 7B is a schematic diagram of another multiplexer 105 that includes surface acoustic wave devices according to an embodiment. The multiplexer 105 can be a duplexer. The multiplexer 105 includes a transmit filter and a receive filter. For example, the transmit filter can be a band pass filter. The illustrated transmit filter in the multiplexer 105 is arranged to filter a radio frequency signal received at a transmit port TX and provide a filtered output signal to an antenna port ANT. The illustrated receive filter in the multiplexer 105 is arranged to filter a radio frequency signal received at the antenna port ANT and provide a filtered output to a receive port RX. The transmit filter includes resonators rt01 to rt08. The resonators rt02, rt04, rt06, rt08 are series resonators and rt01, rt03, rt05, rt07 are shunt resonators. The receive filter includes resonators rr11 to rr15, and a multi-mode SAW filter (e.g., a double mode SAW filter dms1). The resonators rr1, rr13, rr15 are series resonators and the resonators rr12, rr14 are shunt resonators.

The multiplexer 105 also includes capacitors coupled in parallel with the resonators rt01, rt03, rt05, rt07, rt12, rt13, rr14, rr15 and with the DMS filter dms1. The capacitors can include one or more capacitors in accordance with any suitable principles and advantages disclosed herein.

Any suitable filter topology can include a capacitor in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

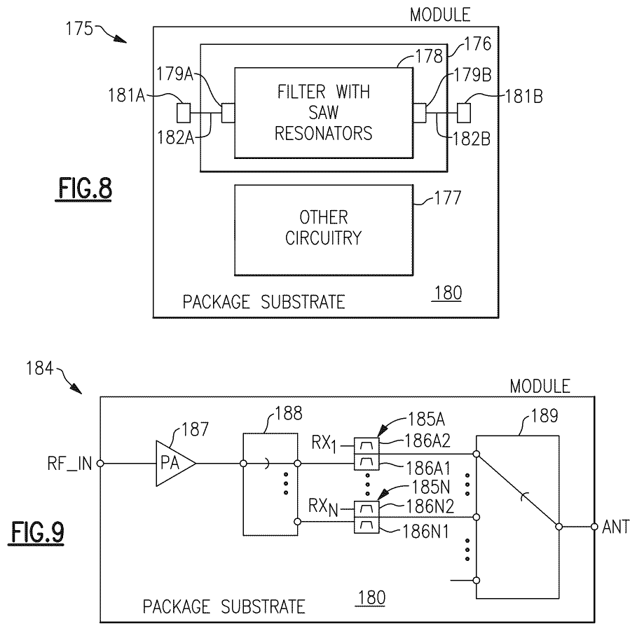

FIG. 8 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 8 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 8. The packaging substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 9 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate 180 can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 9 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

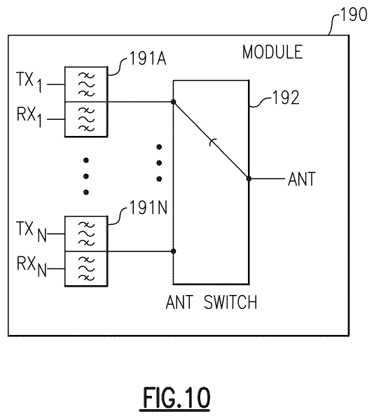

FIG. 10 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

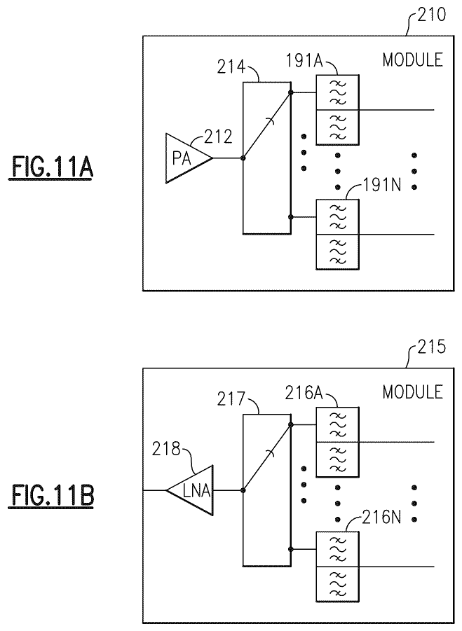

FIG. 11A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 11B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

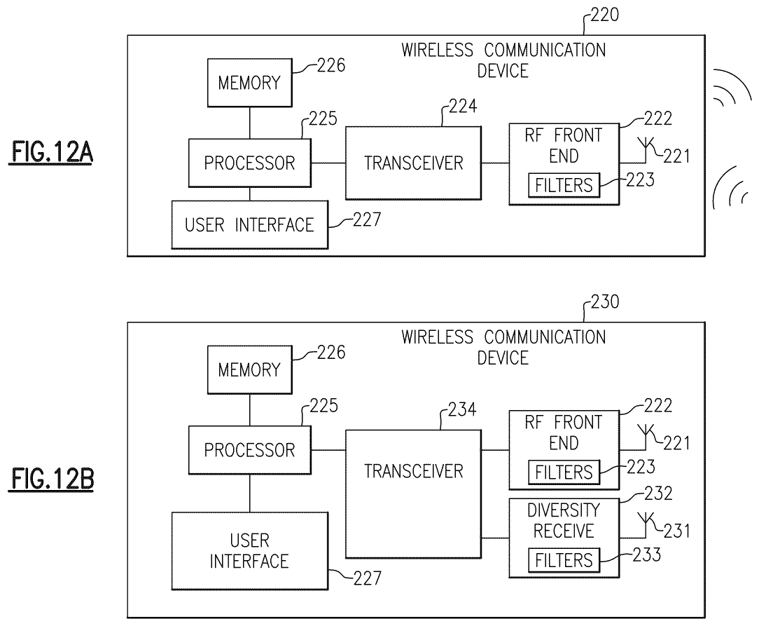

FIG. 12A is a schematic diagram of a wireless communication device 220 that includes filters 223 in a radio frequency front end 222 according to an embodiment. The filters 223 can include one or more acoustic wave devices in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 12B is a schematic diagram of a wireless communication device 230 that includes filters 223 in a radio frequency front end 222 and a second filter 233 in a diversity receive module 232. The wireless communication device 230 is like the wireless communication device 220 of FIG. 12A, except that the wireless communication device 230 also includes diversity receive features. As illustrated in FIG. 12B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to. ” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a resonator; and
a capacitor electrically coupled to the resonator, the capacitor including a first conductive layer, a second conductive layer, and a dielectric material between the first conductive layer and the second conductive layer, the dielectric material having a negative temperature coefficient of permittivity.

2. The acoustic wave device of claim 1 wherein the resonator is electrically coupled in series with the capacitor.

3. The acoustic wave device of claim 1 wherein the resonator is electrically coupled in parallel with the capacitor.

4. The acoustic wave device of claim 3 further includes a second capacitor electrically coupled in series with the resonator.

5. The acoustic wave device of claim 1 wherein the dielectric material has a temperature coefficient of permittivity in a range between negative 500 ppm/K and negative 10,000 ppm/K.

6. The acoustic wave device of claim 1 wherein the dielectric material has a temperature coefficient of permittivity in a range between negative 800 ppm/K and negative 5,000 ppm/K.

7. The acoustic wave device of claim 1 wherein the dielectric material includes titanium oxide, barium titanate, lead zirconate titanate, strontium titanate, tantalum oxide, magnesium oxide, or barium strontium titanate.

8. The acoustic wave device of claim 1 wherein the dielectric material includes titanium dioxide.

9. The acoustic wave device of claim 1 wherein the resonator is a surface acoustic wave resonator.

10. The acoustic wave device of claim 9 wherein the resonator is a multilayer piezoelectric substrate surface acoustic wave resonator.

11. The acoustic wave device of claim 1 wherein the resonator is a bulk acoustic wave resonator.

12. The acoustic wave device of claim 1 wherein the capacitor is formed on a multilayer piezoelectric substrate.

13. The acoustic wave device of claim 12 wherein the multilayer piezoelectric substrate includes a support substrate, a piezoelectric layer, and an intermediate layer between the support substrate and the piezoelectric layer.

14. The acoustic wave device of claim 1 wherein the first conductive layer of the capacitor and an interdigital transducer electrode of the resonator includes the same material.

15. A capacitor configured to couple to an acoustic wave resonator, the capacitor comprising:
a first conductive layer;
a second conductive layer; and
an insulator between the first conductive layer and the second conductive layer, the insulator including a dielectric material having a negative temperature coefficient of
permittivity.

16. The capacitor of claim 15 wherein the dielectric material has a temperature coefficient of permittivity in a range between negative 500 ppm/K and negative 10,000 ppm/K.

17. A method of forming an acoustic wave device, the method comprising:
providing a resonator; and
electrically coupling a capacitor to the resonator, the capacitor including a first conductive layer, a second conductive layer, and a dielectric material between the first conductive layer and the second conductive layer, the dielectric material having a negative temperature coefficient of permittivity.

18. The method of claim 17 wherein electrically coupling the capacitor to the resonator includes connecting the capacitor in series with the resonator.

19. The method of claim 17 wherein electrically coupling the capacitor to the resonator includes connecting the capacitor in parallel with the resonator.

20. The method of claim 17 wherein the dielectric material includes titanium oxide, barium titanate, lead zirconate titanate, strontium titanate, tantalum oxide, magnesium oxide, or barium strontium titanate.
